(19) United States
(12) Patent Application Publication
(10) Pub. No.: US 2026/0299400 A1
(43) Pub. Date: Oct. 1, 2026

(54) METHOD OF AND DEVICE FOR GENERATING LAYOUT DIAGRAM

(71) Applicant: Taiwan Semiconductor Manufacturing Company, Ltd., Hsinchu (TW)

(72) Inventors: Jia-Guei JOU, Hsinchu (TW); Hsin-Lun TSENG, Hsinchu (TW); Yu-Tung CHEN, Hsinchu (TW); Wei-Lin CHU, Hsinchu (TW)

(73) Assignee: Taiwan Semiconductor Manufacturing Company, Ltd., Hsinchu (TW)

(21) Appl. No.: 19/093,513

(22) Filed: Mar. 28, 2025

(51) Int. Cl. G03F 1/36; G06F 30/392

(52) U.S. Cl. CPC G03F 1/36; G06F 30/392

(57) ABSTRACT

An embodiment method of generating a layout diagram for a layer of a semiconductor device includes obtaining an initial layout diagram that includes a first set of layout patterns of the layout diagram indicative of a first set of elements of the layer of the semiconductor device, the first set of elements being mappable to a circuit design of the semiconductor device. The method includes placing a second set of layout patterns of the layout diagram indicative of a second set of elements of the layer of the semiconductor device, the second set of elements not being mappable to the circuit design of the semiconductor device. Each one of the second set of layout patterns has a freeform shape that corresponds to having an irregular contour, being asymmetrical, or both.

### BACKGROUND

The semiconductor integrated circuit (IC) industry has experienced rapid growth. In the course of IC evolution, functional density (i.e., the number of interconnected devices per chip area) has generally increased while geometric size (i.e., scale of the smallest component (or line) that can be created using a fabrication process, measurable as a critical dimension in some applications) has decreased. This scaling-down process generally provides benefits by increasing production efficiency and reducing associated costs.

Various processing steps are used to fabricate IC components on a semiconductor wafer. These steps include formation of one or more photoresist and/or hardmask patterns on the semiconductor wafer in conjunction with one or more deposition processes, removal processes, and cleaning processes. In some applications, photolithography is utilized to transfer a pattern from a photomask onto a semiconductor wafer to form a photoresist and/or hardmask pattern. In some applications, an etching process is performed to partially remove the deposited materials based on the photoresist and/or hardmask pattern. However, during the same etching process, the etching rates at different regions may vary based on the corresponding pattern densities (in particular, the densities of unmasked portions) of the regions. In some embodiments, the increased etching rate inconsistency may cause negative impact in the control of critical dimensions of the IC components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of an integrated circuit (IC) manufacturing system, and an IC manufacturing flow associated therewith, in accordance with some embodiments.

FIGS. 2A-2B are plan views of various layout patterns for a layer of a semiconductor device at different stages of a first mask data preparation example, in accordance with some embodiments.

FIG. 3 is a plan view of various layout patterns for a layer of a semiconductor device based on a second mask data preparation example, in accordance with some embodiments.

FIGS. 4A-4C are plan views of freeform dummy pattern examples, in accordance with some embodiments.

FIG. 5 is a plan view of a photomask for a layer of a semiconductor device, in accordance with some embodiments.

FIG. 6 is a flowchart of a method of generating a layout diagram for a layer of a semiconductor device, in accordance with some embodiments.

FIG. 7 is a block diagram of an electronic design automation (EDA) system in accordance with some embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B, and C” means “A, B, and/or C” (A, B, C, A and B, A and C, B and C, or A, B and C), and does not mean one element from A, one element from B, and one element from C, unless otherwise described.

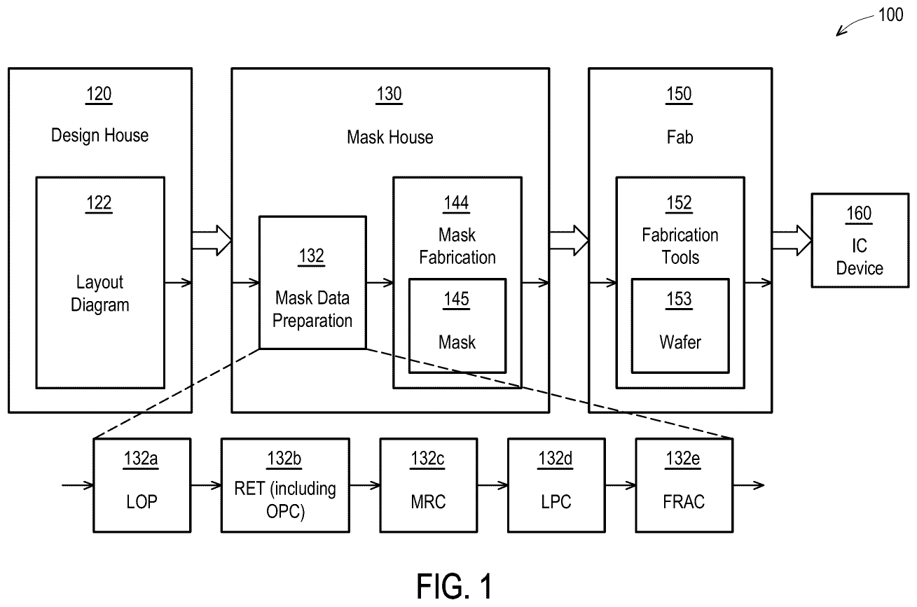

FIG. 1 is a block diagram of an integrated circuit (IC) manufacturing system 100, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 100.

In FIG. 1, IC manufacturing system 100 includes entities, such as a design house 120, a mask house 130, and an IC manufacturer/fabricator (fab) 150, that interact with one another in the design, development, and manufacturing cycles and/or services related to manufacturing an IC device 160. The entities in system 100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 120, mask house 130, and IC fab 150 are owned by a single larger company. In some embodiments, two or more of design house 120, mask house 130, and IC fab 150 coexist in a common facility and use common resources.

Design house (or design team) 120 generates a layout diagram 122 of an IC design. In some embodiments, layout diagram 122 includes various geometrical patterns designed for an IC device 160. The geometrical patterns correspond to patterns of metal, oxide, or semiconductor layers that make up the various components of IC device 160 to be fabricated. The various layers combine to form various IC features. For example, a portion of layout diagram 122 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 120 implements a proper design procedure to form layout diagram 122. The design procedure includes one or more of logic design, physical design, or place and route. layout diagram 122 is presented in one or more data files having information of the geometrical patterns. For example, layout diagram 122 can be expressed in a GDSII file format or DFII file format.

Mask house 130 includes mask data preparation 132 and mask fabrication 144. Mask house 130 uses layout diagram 122 to manufacture one or more masks 145 to be used for fabricating the various layers of IC device 160 according to layout diagram 122. Mask house 130 performs mask data preparation 132, where layout diagram 122 is translated into a representative data file (RDF). Mask data preparation 132 provides the RDF to mask fabrication 144. Mask fabrication 144 includes a mask writer. A mask writer converts the RDF to an image on a substrate, such as a mask (reticle) 145 or a semiconductor wafer 153. Layout diagram 122 is manipulated by mask data preparation 132 to comply with particular characteristics of the mask writer and/or requirements of IC fab 150. In FIG. 1, mask data preparation 132 and mask fabrication 144 are illustrated as separate elements. In some embodiments, mask data preparation 132 and mask fabrication 144 can be collectively referred to as mask data preparation.

In some embodiments, mask data preparation 132 includes various stages, including one or more of a logic operation (LOP) stage 132a, a resolution enhancement technique (RET) (RET) stage 132b, a mask rule checker (MRC) stage 132c, and a lithography process checking (LPC) stage 132d. In some embodiments, each one of the above-noted stages receives an input layout diagram from a previous stage in the GDSII file format or DFII file format, and outputs a processed result as an output layout diagram to a subsequent stage in the GDSII file format or DFII file format. In some embodiments, some stages and/or operations described herein are omitted, and some additional stages and/or operations are included in mask data preparation 132. In some embodiments, these stages are performed based on an order different from the example in FIG. 1.

In some embodiments, LOP stage 132a corresponds to modifying an input layout diagram (e.g., the layout diagram 122 from design house 120) according to manufacturing rules. In some embodiments, LOP stage 132a includes checking whether the input layout diagram meets a set of rules derived based on various manufacturer constraints and modifying the input layout diagram accordingly to obtain an output layout diagram that meets the set of rules.

In some embodiments, RET stage 132b corresponds to modifying the input layout diagram (e.g., the output layout diagram from LOP stage 132a) to obtain an output layout diagram that compensates for various limitations in lithographic processes used to manufacture IC device 160. In some embodiments, RET stage 132b includes a rule-based optical proximity correction (OPC) process and/or model-based OPC process that corresponds to using lithography enhancement techniques to compensate for image errors, such as those that can arise from diffraction, interference, other process effects and the like. In some embodiments, RET stage 132b further includes one or more other enhancement techniques, such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, MRC stage 132c corresponds to checking the layout diagram that has undergone processes in RET stage with a set of mask creation rules, which contain certain geometric and/or connectivity restrictions to ensure sufficient margins, to account for variability in semiconductor manufacturing processes, and the like. In some embodiments, MRC stage 132c also corresponds to modifying the layout diagram to compensate for photolithographic implementation effects during mask fabrication 144, which may undo part of the modifications performed by OPC of RET stage 132b in order to meet mask creation rules.

In some embodiments, LPC stage 132d corresponds to simulating processing that will be implemented by IC fab 150 to fabricate IC device 160. The simulation at LPC stage 132d is based on the layout diagram from the previous stage (e.g., MRC stage 132c) to create a simulated manufactured device representing IC device 160. The processing parameters in LPC simulation can include parameters associated with various processes of the IC manufacturing cycle, parameters associated with tools used for manufacturing the IC, and/or other aspects of the manufacturing process. The simulation at LPC stage 132d takes into account various factors, such as aerial image contrast, depth of focus (DOF), mask error enhancement factor (MEEF), other suitable factors, and the like or combinations thereof. In some embodiments, after a simulated manufactured device has been created at LPC stage 132d, if the simulated device is not close enough in shape to satisfy design rules, the process proceeds to repeat RET stage 132b and/or MRC stage 132c to further refine the layout diagram.

In this example, after LPC stage 132d, mask data preparation 132 further includes a fracturing process (FRAC) stage 132e. In some embodiments, FRAC stage 132e receives an input layout diagram from a previous stage (e.g., LPC stage 132d) in the GDSII file format or DFII file format and outputs a processed result to a subsequent stage (e.g., mask fabrication 144) as a mask file in an RDF format. In some embodiments, FRAC stage 132e corresponds to “fracture” the designed features into polygons or other component shapes suitable for mask production.

After mask data preparation 132 and during mask fabrication 144, a mask 145 or a group of masks 145 are fabricated based on the modified layout diagram and/or the mask file converted from the modified layout diagram. In some embodiments, mask fabrication 144 includes performing one or more lithographic exposures based on the modified layout diagram and/or mask file from mask data preparation 132. In some embodiments, an electron-beam (e-beam) or a mechanism of multiple e-beams is used to form a pattern on a mask (photomask or reticle) 145 based on the modified layout diagram and/or the mask file. Mask 145 can be formed in various technologies. In some embodiments, mask 145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 145 includes a transparent substrate (e.g., fused quartz) and an opaque material (e.g., chromium) coated in the opaque regions of the binary mask. In another example, mask 145 is formed using a phase shift technology. In a phase shift mask (PSM) version of mask 145, various features in the pattern formed on the phase shift mask are configured to have proper phase difference to enhance the resolution and imaging quality. In various examples, the phase shift mask can be attenuated PSM or alternating PSM. The mask(s) generated by mask fabrication 144 is used in a variety of processes. For example, such a mask(s) is used in an ion implantation process to form various doped regions in semiconductor wafer 153, in an etching process to form various etching regions in semiconductor wafer 153, and/or in other suitable processes.

IC fab 150 is an IC fabrication business that includes one or more manufacturing facilities for the fabrication of a variety of different IC products. In some embodiments, IC Fab 150 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 150 includes fabrication tools 152 configured to execute various manufacturing operations on semiconductor wafer 153 such that IC device 160 is fabricated in accordance with the mask(s), e.g., mask 145. In various embodiments, fabrication tools 152 include one or more of a wafer stepper, an ion implanter, a photoresist coater, a process chamber, e.g., a chemical vapor deposition (CVD) chamber or low-pressure chemical vapor deposition (LPCVD) furnace, a chemical mechanical polishing (CMP) system, a plasma etch system, a wafer cleaning system, or other manufacturing equipment capable of performing one or more suitable manufacturing processes as discussed herein.

IC fab 150 uses mask(s) 145 fabricated by mask house 130 to fabricate IC device 160. Thus, IC fab 150 at least indirectly uses layout diagram 122 to fabricate IC device 160. In some embodiments, semiconductor wafer 153 is fabricated by IC fab 150 using mask(s) 145 to form IC device 160. In some embodiments, the IC fabrication includes performing one or more lithographic exposures based at least indirectly on layout diagram 122. Semiconductor wafer 153 includes a silicon substrate or other proper substrate having material layers formed thereon. Semiconductor wafer 153 further includes one or more of various doped regions, dielectric features, multilevel interconnects, and the like (formed at subsequent manufacturing steps).

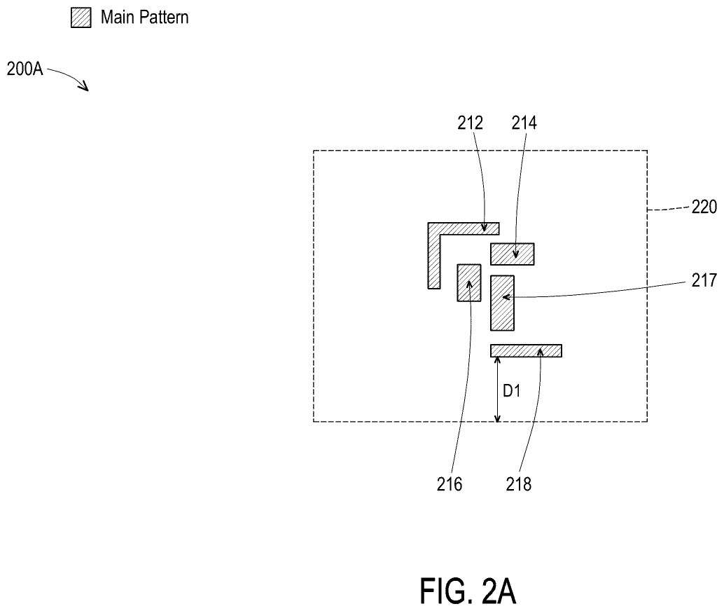

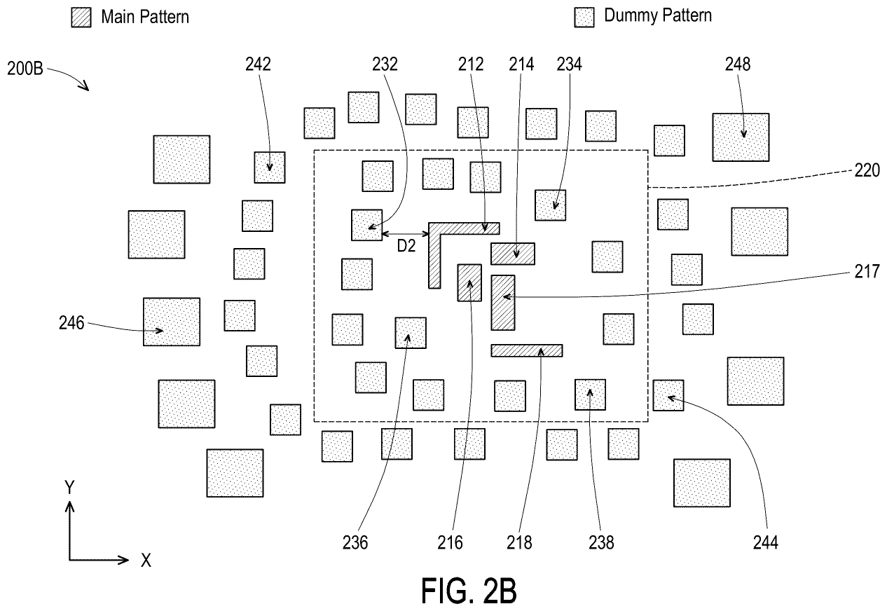

FIG. 2A is a plan view of various layout patterns included in a layout diagram 200A for a layer of a semiconductor device based on a first mask data preparation example, in accordance with some embodiments. In some embodiments, layout diagram 200A corresponds to an input layout diagram at an LOP stage (e.g., LOP stage 132a in FIG. 1) of the first mask data preparation example. FIG. 2A includes a portion of layout diagram 200A, and some features and/or details of layout diagram 200A are not included in FIG. 2A.

In FIG. 2A, layout diagram 200A includes a first set of layout patterns (corresponding to the legend labeled as “main pattern”), including main patterns 212, 214, 216, 217, and 218. In this example, main patterns 212, 214, 216, 217, and 218 are indicative of a first set of elements of a layer of a semiconductor device, such as a polysilicon layer, a metallization layer, a dielectric layer (e.g., for forming gate dielectrics or BEOL components), or the like. In some embodiments, the first set of elements is mappable to a circuit design of the semiconductor device. Layout diagram 200A further includes a dummy pattern boundary 220. In some embodiments, dummy pattern boundary 220 is defined based on the first set of layout patterns. In some embodiments, dummy pattern boundary 220 is defined based on a distance between any point of dummy pattern boundary 220 and any point of the first set of layout patterns being no less than a reference distance. For example, the distance D1 between main pattern 218 and the closest point of dummy pattern boundary 220 is set to be equal to or greater than the reference distance. In some embodiments, the reference distance corresponds to an OPC ambit of a subsequent OPC process (e.g., an OPC process at RET stage 132b in FIG. 1). In some embodiments, the reference distance ranges from 2 micrometers (μm) to 20 μm.

FIG. 2B is a plan view of various layout patterns included in a layout diagram 200B that corresponds to an output layout diagram at the LOP stage (e.g., LOP stage 132a in FIG. 1) of the first mask data preparation example based on layout diagram 200A in FIG. 2A, in accordance with some embodiments. Components in FIG. 2B that are the same or similar to those in FIG. 2A are given the same reference numbers, and description thereof is simplified or omitted.

At the LOP stage (e.g., LOP stage 132a in FIG. 1), in order to improve the etching rate inconsistency for the features corresponding to main patterns 212, 214, 216, 217, and 218, a plurality of dummy patterns (corresponding to the legend labeled as “dummy pattern”) are placed into layout diagram 200B. In this example, the plurality of dummy patterns includes a second set of layout patterns within dummy pattern boundary 220 (e.g., dummy patterns 232, 234, 236, and 238) and a third set of dummy patterns outside dummy pattern boundary 220 (e.g., dummy patterns 242, 244, 246, and 248). In some embodiments, the second set of layout patterns is indicative of a second set of elements of the layer of the semiconductor device, and the third set of layout patterns is indicative of a third set of elements of the layer of the semiconductor device. In some embodiments, the second set of elements and the third set of elements are not mappable to the circuit design of the semiconductor device.

In this example, each one of the plurality of dummy patterns has a square shape or a rectangular shape with predetermined sizes based on the cell library or layout library prepared for the mask data preparation process. In some embodiments, an area of a dummy pattern inside dummy pattern boundary 220 (e.g., dummy pattern 232) is equal to or less than a dummy pattern outside dummy pattern boundary 220 (e.g., dummy pattern 242). In some embodiments, an area of a dummy pattern outside and closer to dummy pattern boundary 220 (e.g., dummy pattern 242) is equal to or less than a dummy pattern outside and farther from dummy pattern boundary 220 (e.g., dummy pattern 246). In some embodiments, a distance between any dummy pattern and any of the first set of layout patterns is no less than a reference spacing. For example, the distance D2 between main pattern 212 and the closest dummy pattern 232 is set to be equal to or greater than the reference spacing. In some embodiments, the reference spacing ranges from 1 μm to 3 μm.

In some embodiments, the layout diagram before the LOP stage already includes a portion or all of the dummy patterns in FIG. 2B, and dummy patterns are checked and/or modified at the LOP stage to ensure the validity and compliance of the constraints applicable to the dummy patterns.

In some embodiments, because the sides of the main patterns 212, 214, 216, 217, and 218 and the sides of the dummy patterns within dummy pattern boundary 220 (e.g., dummy patterns 232, 234, 236, and 238) run along a first direction (e.g., the X direction) or a second direction (e.g., the Y direction), as well as the fixed sizes and shapes of the dummy patterns, there is a limit as to the total area and density of the added dummy patterns.

In some embodiments, according to a second mask data preparation example described below, the square or rectangular dummy patterns within dummy pattern boundary 220 are replaced with dummy patterns that have freeform shapes. Based on the added flexibility of the shapes and sizes of freeform dummy patterns, the total area and density of the added dummy patterns may be increased or better adjusted with respect to other portions of the wafer, compared to the example in FIG. 2B. In some embodiments, increasing the range or capability of adjusting the total area and density of the added dummy patterns corresponds to increasing the control over the etching rate consistency and the control of critical dimensions of the elements of a corresponding layer of a semiconductor device.

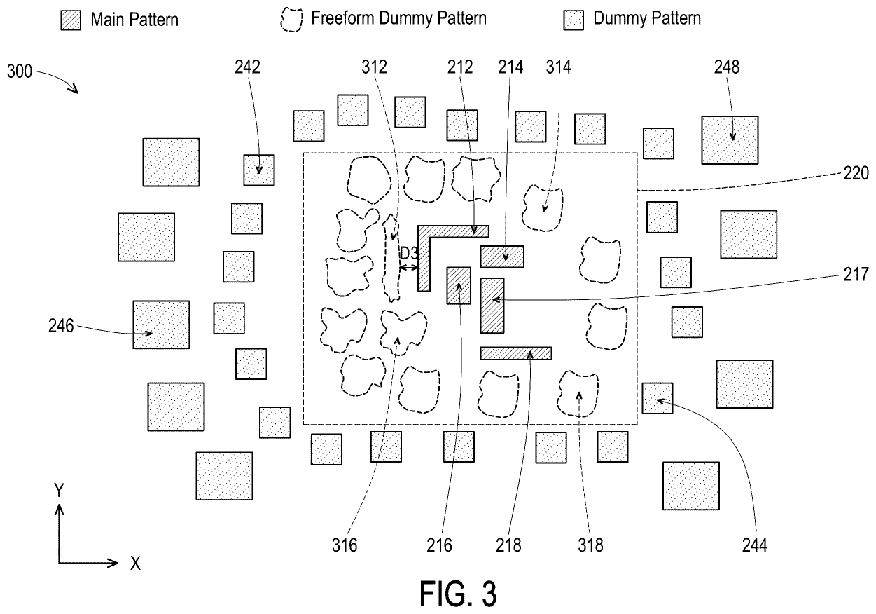

FIG. 3 is a plan view of various layout patterns included in a layout diagram 300 for a layer of a semiconductor device based on a second mask data preparation example, in accordance with some embodiments. In some embodiments, layout diagram 300 corresponds to an output layout diagram at the LOP stage (e.g., LOP stage 132a in FIG. 1) of the second mask data preparation example based on layout diagram 200A in FIG. 2A. Components in FIG. 3 that are the same or similar to those in FIGS. 2A-2B are given the same reference numbers, and description thereof is simplified or omitted.

In FIG. 3, layout diagram 300 includes a first set of layout patterns (e.g., including main patterns 212, 214, 216, 217, and 218 and corresponding to the legend labeled as “main pattern”) that is the same or similar to the first set of layout patterns in layout diagram 200B. In FIG. 3, layout diagram 300 includes a different second set of layout patterns (e.g., freeform dummy patterns 312, 314, 316, and 318, corresponding to the legend labeled as “freeform dummy pattern”) within dummy pattern boundary 220. Compared to layout diagram 200B, each one of the second set of layout patterns in layout diagram 300 has a freeform shape that corresponds to having an irregular contour, being asymmetrical, or both. In some embodiments, each one of the second set of layout patterns in layout diagram 300 has a unique shape or a unique size among the second set of layout patterns. In some embodiments, a minimal distance between any point of the first set of layout patterns and any point of the second set of layout patterns ranges from 100 nanometers (nm) to 500 nm. For example, a distance D3 between main pattern 212 and freeform dummy pattern 312 is not less than 100 nm.

Moreover, layout diagram 300 includes a third set of layout patterns (e.g., including dummy patterns 242, 244, 246, and 248 and corresponding to the legend labeled as “dummy pattern”) that is outside dummy pattern boundary 220 and the same or similar to the third set of layout patterns in layout diagram 200B. In this example, each one of the third set of layout patterns outside dummy pattern boundary 220 has a square shape or a rectangular shape as described with respect to layout diagram 200B.

In some embodiments according to a first scenario, layout diagram 300 in FIG. 3 is the result of processing layout diagram 200A at the LOP stage (e.g., LOP stage 132a in FIG. 1) of the second mask data preparation example. In the first scenario, the freeform dummy patterns and the square/rectangular dummy patterns are inserted at the LOP stage. In some embodiments according to a second scenario, layout diagram 300 in FIG. 3 is the result of processing layout diagram 200B at the LOP stage of the second mask data preparation example. In some embodiments according to the second scenario, a portion of the square/rectangular dummy patterns within the dummy pattern boundary (e.g., based on OPC ambit) is replaced by the freeform dummy patterns at the LOP stage. In some embodiments according to the second scenario, a portion of the square/rectangular dummy patterns within the dummy pattern boundary is omitted, and the freeform dummy patterns are inserted within the dummy pattern boundary as appropriate at the LOP stage.

In some embodiments, based on having the freeform shapes, the freeform dummy patterns are distributed more evenly within dummy pattern boundary 220 to fill the blank space not occupied by the first set of layout patterns (i.e., main patterns). According to one or more embodiments based on the second mask data preparation example compared to a comparable implementation based on the first mask data preparation example, the freeform dummy patterns are more evenly distributed and increase the total area of the added dummy patterns by at least 15% within the dummy pattern boundary. As a result, the control over etching rate consistency and the control of critical dimensions of the elements of a corresponding layer of a semiconductor device are improved based on using freeform dummy patterns.

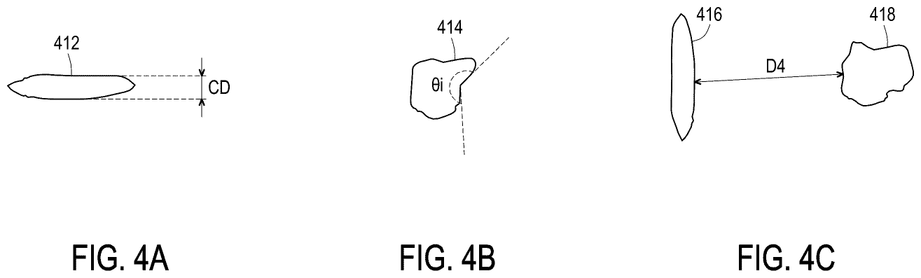

FIG. 4A is a plan view of a first freeform dummy pattern example 412, in accordance with some embodiments. In some embodiments, a minimum critical dimension of any of the freeform dummy patterns in FIG. 3, represented by a critical dimension CD of first freeform dummy pattern 412, ranges from 10 nm to 100 nm. In some embodiments, a minimal area of any of the freeform dummy patterns in FIG. 3, represented by first freeform dummy pattern 412, ranges from 0.01 square micrometers (μm²) to 0.25 μm².

FIG. 4B is a plan view of a second freeform dummy pattern example 414, in accordance with some embodiments. In some embodiments, any interior angle of any of the freeform dummy patterns in FIG. 3, represented by an interior angle θi of second freeform dummy pattern 414, is equal to or less than 250 degrees.

FIG. 4C is a plan view of a third freeform dummy pattern example 416 and a fourth freeform dummy pattern example 418, in accordance with some embodiments. In some embodiments, a minimal distance between any two of the freeform dummy patterns in FIG. 3, represented by a distance D4 between third freeform dummy pattern 416 and fourth freeform dummy pattern 418, ranges from 100 nm to 500 nm.

In some embodiments, in view of the constraints with respect to the examples in FIGS. 4A-4C, the sizes and shapes of the freeform dummy patterns are determinable based on a set of predetermined freeform patterns stored in a processing device (e.g., the processing device configured to perform mask data preparation), a set of randomly generated patterns, or a shape, a size, or a parameter from a user input, or a combination thereof.

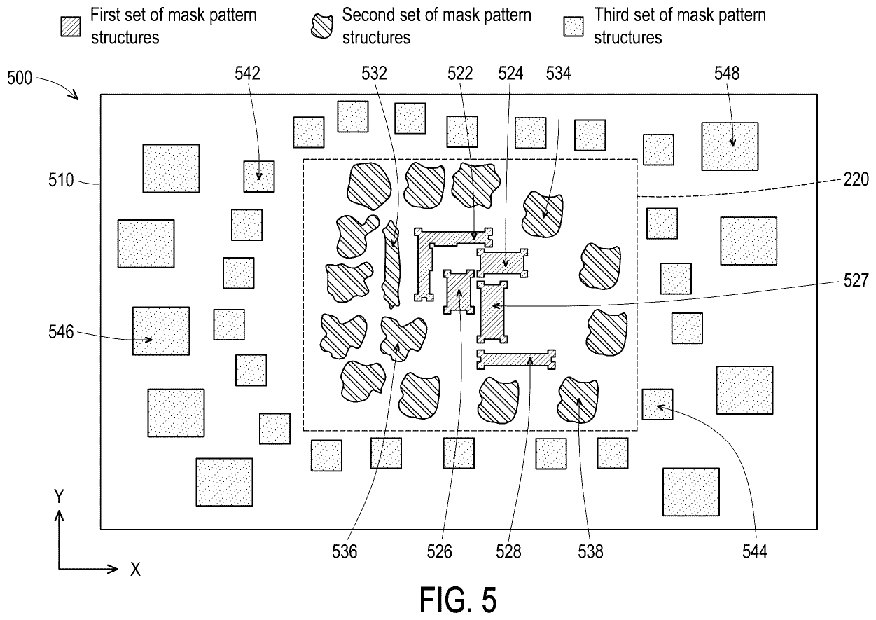

FIG. 5 is a plan view of a photomask 500 for a layer of a semiconductor device, in accordance with some embodiments. In this example, the layout diagram 300 in FIG. 3 is further processed based on one or more processing stages of mask data preparation (e.g., mask data preparation 132 in FIG. 1), including OPC for example, and photomask 500 is manufactured according to the result of the mask data preparation based on layout diagram 300. The plan view of photomask 500 in FIG. 5 is a simplified plan view of a portion of photomask 500, and some features of photomask 500 are simplified or omitted in FIG. 5.

In FIG. 5, photomask 500 includes a substrate 510 (e.g., a glass substrate), a first set of mask pattern structures (including structures 522, 524, 526, 527, and 528 and corresponding to the legend labeled as “first set of mask pattern structures”) over substrate 510 and a second set of mask pattern structures (including structures 532, 534, 536, and 538 and corresponding to the legend labeled as “second set of mask pattern structures”) over substrate 510. In some embodiments, the first set of mask pattern structures corresponds to a first set of layout patterns of the layout diagram indicative of a first set of elements of the layer of the semiconductor device, and the first set of elements is mappable to a circuit design of the semiconductor device. In this example, structures 522, 524, 526, 527, and 528 correspond to main patterns 212, 214, 216, 217, and 218 of layout diagram 300 in FIG. 3. In some embodiments, the second set of mask pattern structures corresponds to a second set of layout patterns of the layout diagram indicative of a second set of elements of the layer of the semiconductor device, and the second set of elements is not mappable to the circuit design of the semiconductor device. In this example, structures 532, 534, 536, and 538 correspond to freeform dummy patterns 312, 314, 316, and 318 of layout diagram 300 in FIG. 3.

In some embodiments, a dummy pattern boundary 220 (corresponding to dummy pattern boundary 220 in FIGS. 2A-3) is defined based on the first set of layout patterns. In some embodiments, a distance between any point of the dummy pattern boundary and any point of the first set of layout patterns being no less than a reference distance, as described with respect to the example in FIG. 2A. In some embodiments, the first set of layout patterns is within dummy pattern boundary 220, and the second set of layout patterns is within dummy pattern boundary 220. In some embodiments, each one of the second set of layout patterns has a freeform shape that corresponds to having an irregular contour, being asymmetrical, or both, as described with respect to the examples in FIGS. 3-4C. In some embodiments, each one of the second set of layout patterns has a unique shape or a unique size among the second set of layout patterns.

In some embodiments, the first set of mask pattern structures is based on a first set of processed layout patterns that is obtained by applying an OPC process on the first set of layout patterns. In some embodiments, the second set of mask pattern structures is based on a second set of processed layout patterns that is obtained by applying the OPC process on the second set of layout patterns. In some embodiments, the reference distance corresponds to an OPC ambit of the OPC process.

In some embodiments, as described with respect to the example in FIG. 3, a minimal distance between any point of the first set of layout patterns and any point of the second set of layout patterns ranges from 100 nm to 500 nm. In some embodiments, as described with respect to the example in FIG. 4A, a minimum critical dimension of any of the second set of layout patterns ranges from 10 nm to 100 nm. In some embodiments, as described with respect to the example in FIG. 4A, a minimal area of any of the second set of layout patterns ranges from 0.01 μm² to 0.25 μm².In some embodiments, as described with respect to the example in FIG. 4B, any interior angle of any of the second set of layout patterns is equal to or less than 250 degrees. In some embodiments, as described with respect to the example in FIG. 4C, a minimal distance between any two of the second set of layout patterns ranges from 100 nm to 500 nm.

In FIG. 5, photomask 500 further includes a third set of mask pattern structures (including structures 542, 544, 546, and 548 and corresponding to the legend labeled as “third set of mask pattern structures”) over substrate 510. In some embodiments, the third set of mask pattern structures corresponds to a third set of layout patterns of the layout diagram indicative of a third set of elements of the layer of the semiconductor device, and the third set of elements is not mappable to the circuit design of the semiconductor device. In this example, structures 542, 544, 546, and 548 correspond to dummy patterns 242, 244, 246, and 248 of layout diagram 300 in FIG. 3. In this example, each one of the third set of layout patterns has a square shape or a rectangular shape as described with respect to the example in FIG. 3.

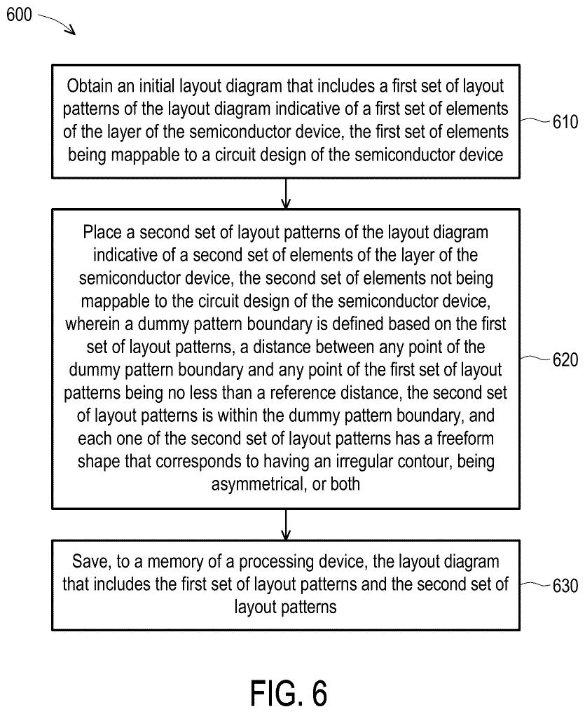

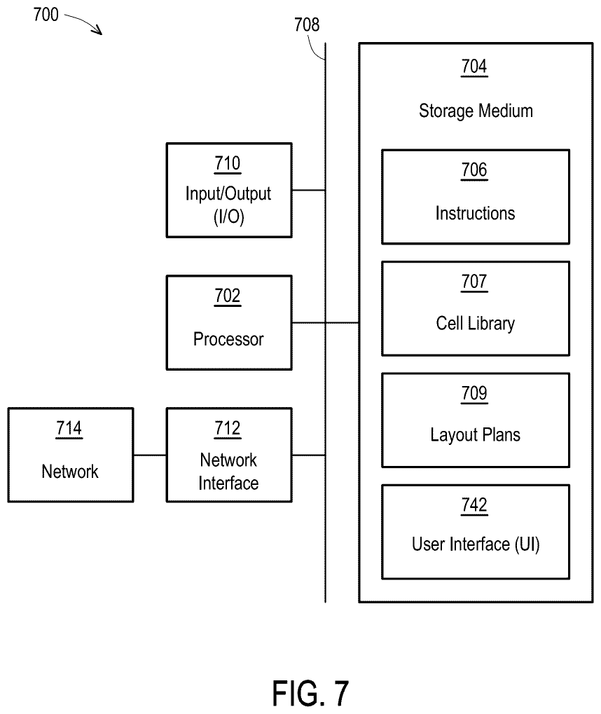

FIG. 6 is a flowchart of a method 600 of generating a layout diagram for a layer of a semiconductor device, in accordance with some embodiments. Method 600 is implementable, for example, using EDA system 700 (FIG. 7, discussed below) and an integrated circuit (IC), manufacturing system 100 in FIG. 1, in accordance with some embodiments. In some embodiments, method 600 is part of a mask data preparation process, such as mask data preparation 132 in FIG. 1. Examples of a layout diagram which can be generated according to method 600 include layout diagram 300 in FIG. 3 in view of the examples in FIGS. 4A-4C. In FIG. 6, method 600 includes blocks 610-630.

At block 610, an initial layout diagram (e.g., layout diagram 200A in FIG. 2A or layout diagram 200B in FIG. 2B) that includes a first set of layout patterns (e.g., the main patterns in layout diagram 200A, layout diagram 200B, or layout diagram 300) of the layout diagram (e.g., layout diagram 300) indicative of a first set of elements of the layer of the semiconductor device. In some embodiments, the first set of elements is mappable to a circuit design of the semiconductor device.

At block 620, a second set of layout patterns (e.g., the freeform dummy patterns in layout diagram 300) of the layout diagram indicative of a second set of elements of the layer of the semiconductor device. In some embodiments, the second set of elements is not mappable to the circuit design of the semiconductor device.

In some embodiments, a dummy pattern boundary (e.g., dummy pattern boundary 220) is defined based on the first set of layout patterns, and a distance between any point of the dummy pattern boundary and any point of the first set of layout patterns is no less than a reference distance. In some embodiments, the second set of layout patterns is within the dummy pattern boundary. In some embodiments, each one of the second set of layout patterns has a freeform shape that corresponds to having an irregular contour, being asymmetrical, or both.

In some embodiments, each one of the second set of layout patterns has a unique shape or a unique size among the second set of layout patterns. In some embodiments, method 600 further includes generating the second set of layout patterns based on each one of the second set of layout patterns having a unique shape or a unique size among the second set of layout patterns. In some embodiments, method 600 further includes generating the second set of layout patterns based on a minimum critical dimension of any of the second set of layout patterns ranges from 10 nm to 100 nm as described with respect to the example in FIG. 4A, a minimal area of any of the second set of layout patterns ranges from 0.01 μm² to 0.25 μm² as described with respect to the example in FIG. 4A, any interior angle of any of the second set of layout patterns is equal to or less than 250 degrees as described with respect to the example in FIG. 4B, or a combination thereof. In some embodiments, method 600 further includes generating the second set of layout patterns based on a set of predetermined freeform patterns stored in the processing device, a set of randomly generated patterns, a shape, a size, or a parameter from a user input, or a combination thereof. In some embodiments, as described with respect to the example in FIG. 4C, the placing the second set of layout patterns is based on a minimal distance between any two of the second set of layout patterns ranges from 100 nm to 500 nm.

At block 630, the layout diagram (e.g., layout diagram 300) that includes the first set of layout patterns and the second set of layout patterns is saved to a memory of a processing device (e.g., the processing device configured to perform the mask data preparation process).

In some embodiments, method 600 further includes omitting a third set of layout patterns of the initial layout diagram (e.g., taking layout diagram 200B in FIG. 2B as the initial layout diagram) within the dummy pattern boundary and indicative of a third set of elements of the layer of the semiconductor device, where the third set of elements is not mappable to the circuit design of the semiconductor device. In some embodiments, the third set of layout patterns corresponds to the dummy patterns within dummy pattern boundary 220 in FIG. 2B. In some embodiments as described with respect to the example in FIG. 2B, each one of the third set of layout patterns has a square shape or a rectangular shape.

In some embodiments, method 600 further includes applying an OPC process on the first set of layout patterns and the second set of layout patterns. In some embodiments, the reference distance corresponds to an OPC ambit of the OPC process.

FIG. 7 is a block diagram of an electronic design automation (EDA) system 700 in accordance with some embodiments.

In some embodiments, EDA system 700 includes an automatic placement and routing (APR) system. Methods described herein of designing layout diagrams represent wire routing arrangements, in accordance with one or more embodiments, are implementable, for example, using EDA system 700, in accordance with some embodiments.

In some embodiments, EDA system 700 is a general purpose computing device including a hardware processor 702 and a non-transitory, computer-readable storage medium 704. Storage medium 704, amongst other things, is encoded with, i.e., stores, computer program code 706, i.e., a set of executable instructions. Execution of instructions 706 by hardware processor 702 represents (at least in part) an EDA tool which implements a portion or all of the methods described herein in accordance with one or more embodiments (hereinafter, the noted processes and/or methods).

Processor 702 is electrically coupled to computer-readable storage medium 704 via a bus 708. Processor 702 is also electrically coupled to an I/O interface 710 by bus 708. A network interface 712 is also electrically connected to processor 702 via bus 708. Network interface 712 is connected to a network 714, so that processor 702 and computer-readable storage medium 704 are capable of connecting to external elements via network 714. Processor 702 is configured to execute computer program code 706 encoded in computer-readable storage medium 704 in order to cause system 700 to be usable for performing a portion or all of the noted processes and/or methods. In one or more embodiments, processor 702 is a central processing unit (CPU), a multi-processor, a distributed processing system, an application specific integrated circuit (ASIC), and/or a suitable processing unit.

In one or more embodiments, computer-readable storage medium 704 is an electronic, magnetic, optical, electromagnetic, infrared, and/or a semiconductor system (or apparatus or device). For example, computer-readable storage medium 704 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 704 includes a compact disk-read only memory (CD-ROM), a compact disk-read/write (CD-R/W), and/or a digital video disc (DVD).

In one or more embodiments, storage medium 704 stores computer program code 706 configured to cause system 700 (where such execution represents (at least in part) the EDA tool) to be usable for performing a portion or all of the noted processes and/or methods. In one or more embodiments, storage medium 704 also stores information which facilitates performing a portion or all of the noted processes and/or methods. In one or more embodiments, storage medium 704 stores library 707 of standard cells including such standard cells as disclosed herein. In one or more embodiments, storage medium 704 stores one or more layout diagrams 709 corresponding to one or more layouts disclosed herein.

EDA system 700 includes I/O interface 710. I/O interface 710 is coupled to external circuitry. In one or more embodiments, I/O interface 710 includes a keyboard, keypad, mouse, trackball, trackpad, touchscreen, and/or cursor direction keys for communicating information and commands to processor 702.

EDA system 700 also includes network interface 712 coupled to processor 702. Network interface 712 allows system 700 to communicate with network 714, to which one or more other computer systems are connected. Network interface 712 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 700.

System 700 is configured to receive information through I/O interface 710. The information received through I/O interface 710 includes one or more of instructions, data, design rules, libraries of standard cells, and/or other parameters for processing by processor 702. The information is transferred to processor 702 via bus 708. EDA system 700 is configured to receive information related to a UI through I/O interface 710. The information is stored in computer-readable medium 704 as user interface (UI) 742.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 700. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

In some aspects, a photomask for a layer of a semiconductor device based on a layout diagram of the semiconductor device includes a substrate, a first set of mask pattern structures over the substrate, and a second set of mask pattern structures over the substrate. The first set of mask pattern structures corresponds to a first set of layout patterns of the layout diagram indicative of a first set of elements of the layer of the semiconductor device, and the first set of elements is mappable to a circuit design of the semiconductor device. The second set of mask pattern structures corresponds to a second set of layout patterns of the layout diagram indicative of a second set of elements of the layer of the semiconductor device, and the second set of elements is not mappable to the circuit design of the semiconductor device. A dummy pattern boundary is defined based on the first set of layout patterns, and a distance between any point of the dummy pattern boundary and any point of the first set of layout patterns is no less than a reference distance. The second set of layout patterns is within the dummy pattern boundary. Each one of the second set of layout patterns has a freeform shape that corresponds to having an irregular contour, being asymmetrical, or both.

In some aspects, a method of generating a layout diagram for a layer of a semiconductor device includes obtaining an initial layout diagram that includes a first set of layout patterns of the layout diagram indicative of a first set of elements of the layer of the semiconductor device, the first set of elements being mappable to a circuit design of the semiconductor device. The method includes placing a second set of layout patterns of the layout diagram indicative of a second set of elements of the layer of the semiconductor device, the second set of elements not being mappable to the circuit design of the semiconductor device. The method further includes saving, to a memory of a processing device, the layout diagram that includes the first set of layout patterns and the second set of layout patterns. A dummy pattern boundary is defined based on the first set of layout patterns, and a distance between any point of the dummy pattern boundary and any point of the first set of layout patterns is no less than a reference distance. The second set of layout patterns is within the dummy pattern boundary. Each one of the second set of layout patterns has a freeform shape that corresponds to having an irregular contour, being asymmetrical, or both.

In some aspects, a processing device for generating a layout diagram for a layer of a semiconductor device includes a memory device processing circuitry coupled to the memory device. The processing circuity is configured to obtain an initial layout diagram that includes a first set of layout patterns of the layout diagram indicative of a first set of elements of the layer of the semiconductor device, the first set of elements being mappable to a circuit design of the semiconductor device. The processing circuity is configured to place a second set of layout patterns of the layout diagram indicative of a second set of elements of the layer of the semiconductor device, the second set of elements not being mappable to the circuit design of the semiconductor device. The processing circuity is further configured to save, to the memory device, the layout diagram that includes the first set of layout patterns and the second set of layout patterns. A dummy pattern boundary is defined based on the first set of layout patterns, and a distance between any point of the dummy pattern boundary and any point of the first set of layout patterns is no less than a reference distance. The second set of layout patterns is within the dummy pattern boundary. Each one of the second set of layout patterns has a freeform shape that corresponds to having an irregular contour, being asymmetrical, or both.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A photomask for a layer of a semiconductor device based on a layout diagram of the semiconductor device, comprising:
a substrate;
a first set of mask pattern structures over the substrate, the first set of mask pattern structures corresponding to a first set of layout patterns of the layout diagram indicative of a first set of elements of the layer of the semiconductor device, the first set of elements being mappable to a circuit design of the semiconductor device; and
a second set of mask pattern structures over the substrate, the second set of mask pattern structures corresponding to a second set of layout patterns of the layout diagram indicative of a second set of elements of the layer of the semiconductor device, the second set of elements not being mappable to the circuit design of the semiconductor device,
wherein
a dummy pattern boundary is defined based on the first set of layout patterns, a distance between any point of the dummy pattern boundary and any point of the first set of layout patterns being no less than a reference distance,
the second set of layout patterns is within the dummy pattern boundary, and
each one of the second set of layout patterns has a freeform shape that corresponds to having an irregular contour, being asymmetrical, or both.

2. The photomask of claim 1, wherein
each one of the second set of layout patterns has a unique shape or a unique size among the second set of layout patterns.

3. The photomask of claim 1, wherein
the first set of mask pattern structures is based on a first set of processed layout patterns that is obtained by applying an optical proximity correction (OPC) process on the first set of layout patterns,
the second set of mask pattern structures is based on a second set of processed layout patterns that is obtained by applying the OPC process on the second set of layout patterns, and
the reference distance corresponds to an OPC ambit of the OPC process.

4. The photomask of claim 1, wherein
a minimal distance between any point of the first set of layout patterns and any point of the second set of layout patterns ranges from 100 nanometers to 500 nanometers.

5. The photomask of claim 1, wherein
a minimum critical dimension of any of the second set of layout patterns ranges from 10 nanometers to 100 nanometers.

6. The photomask of claim 1, wherein
a minimal area of any of the second set of layout patterns ranges from 0.01 square micrometers to 0.25 square micrometers.

7. The photomask of claim 1, wherein
any interior angle of any of the second set of layout patterns is equal to or less than 250 degrees.

8. The photomask of claim 1, wherein
a minimal distance between any two of the second set of layout patterns ranges from 100 nanometers to 500 nanometers.

9. The photomask of claim 1, further comprising:
a third set of mask pattern structures over the substrate, the third set of mask pattern structures corresponds to a third set of layout patterns of the layout diagram outside the dummy pattern boundary and indicative of a third set of elements of the layer of the semiconductor device, the third set of elements not being mappable to the circuit design of the semiconductor device,
wherein
each one of the third set of layout patterns has a square shape or a rectangular shape.

10. A method of generating a layout diagram for a layer of a semiconductor device, comprising:
obtaining an initial layout diagram that includes a first set of layout patterns of the layout diagram indicative of a first set of elements of the layer of the semiconductor device, the first set of elements being mappable to a circuit design of the semiconductor device;
placing a second set of layout patterns of the layout diagram indicative of a second set of elements of the layer of the semiconductor device, the second set of elements not being mappable to the circuit design of the semiconductor device; and
saving, to a memory of a processing device, the layout diagram that includes the first set of layout patterns and the second set of layout patterns,
wherein
a dummy pattern boundary is defined based on the first set of layout patterns, a distance between any point of the dummy pattern boundary and any point of the first set of layout patterns being no less than a reference distance,
the second set of layout patterns is within the dummy pattern boundary, and
each one of the second set of layout patterns has a freeform shape that corresponds to having an irregular contour, being asymmetrical, or both.

11. The method of claim 10, further comprising:
omitting a third set of layout patterns of the initial layout diagram within the dummy pattern boundary and indicative of a third set of elements of the layer of the semiconductor device, the third set of elements not being mappable to the circuit design of the semiconductor device,
wherein
each one of the third set of layout patterns has a square shape or a rectangular shape.

12. The method of claim 11, further comprising:
applying an optical proximity correction (OPC) process on the first set of layout patterns and the second set of layout patterns,
wherein
the reference distance corresponds to an OPC ambit of the OPC process.

13. The method of claim 11, further comprising:
generating the second set of layout patterns based on each one of the second set of layout patterns has a unique shape or a unique size among the second set of layout patterns.

14. The method of claim 11, further comprising:
generating the second set of layout patterns based on:
a minimum critical dimension of any of the second set of layout patterns ranges from 10 nanometers to 100 nanometers,
a minimal area of any of the second set of layout patterns ranges from 0.01 square micrometers to 0.25 square micrometers,
any interior angle of any of the second set of layout patterns is equal to or less than degrees, or
a combination thereof.

15. The method of claim 11, further comprising:
generating the second set of layout patterns based on:
a set of predetermined freeform patterns stored in the processing device,
a set of randomly generated patterns,
a shape, a size, or a parameter from a user input, or
a combination thereof.

16. The method of claim 11, wherein
the placing the second set of layout patterns is based on a minimal distance between any two of the second set of layout patterns ranges from 100 nanometers to 500 nanometers.

17. A processing device for generating a layout diagram for a layer of a semiconductor device, comprising:
a memory device; and
processing circuitry coupled to the memory device and configured to:
obtain an initial layout diagram that includes a first set of layout patterns of the layout diagram indicative of a first set of elements of the layer of the semiconductor device, the first set of elements being mappable to a circuit design of the semiconductor device;
place a second set of layout patterns of the layout diagram indicative of a second set of elements of the layer of the semiconductor device, the second set of elements not being mappable to the circuit design of the semiconductor device; and
save, to the memory device, the layout diagram that includes the first set of layout patterns and the second set of layout patterns,
wherein
a dummy pattern boundary is defined based on the first set of layout patterns, a distance between any point of the dummy pattern boundary and any point of the first set of layout patterns being no less than a reference distance,
the second set of layout patterns is within the dummy pattern boundary, and
each one of the second set of layout patterns has a freeform shape that corresponds to having an irregular contour, being asymmetrical, or both.

18. The processing device of claim 17, wherein the processing circuitry is further configured to:
omit a third set of layout patterns of the initial layout diagram within the dummy pattern boundary and indicative of a third set of elements of the layer of the semiconductor device, the third set of elements not being mappable to the circuit design of the semiconductor device,
wherein
each one of the third set of layout patterns has a square shape or a rectangular shape.

19. The processing device of claim 17, wherein the processing circuitry is further configured to:
apply an optical proximity correction (OPC) process on the first set of layout patterns and the second set of layout patterns,
wherein
the reference distance corresponds to an OPC ambit of the OPC process.

20. The processing device of claim 17, wherein the processing circuitry is further configured to:
generate the second set of layout patterns based on:
a minimum critical dimension of any of the second set of layout patterns ranges from 10 nanometers to 100 nanometers,
a minimal area of any of the second set of layout patterns ranges from 0.01 square micrometers to 0.25 square micrometers,
any interior angle of any of the second set of layout patterns is equal to or less than degrees, or
a combination thereof.
